(19) United States
(12) Patent Application Publication
(10) Pub. No.: US 2014/0355183 A1
(43) Pub. Date: Dec. 4, 2014

(54) METHOD OF MANUFACTURING MULTI-LAYER THIN FILM, MEMBER INCLUDING THE SAME AND ELECTRONIC PRODUCT INCLUDING THE SAME

(71) Applicant: SAMSUNG ELECTRONICS CO., LTD., Suwon-si (KR)

(72) Inventors: Jin Hyun CHO, Seoul (KR); Jin Sub KIM, Yongin-si (KR); Hyong Jun YOO, Hwaseong-si (KR); Seo Joon LEE, Suwon-si (KR); Min Chul JUNG, Pyeongtaek-si (KR)

(73) Assignee: SAMSUNG ELECTRONICS CO., LTD., Suwon-si (KR)

(21) Appl. No.: 14/287,704

(22) Filed: May 27, 2014

(30) Foreign Application Priority Data
May 31, 2013 (KR) 10-2013-0062485
Jul. 4, 2013 (KR) 10-2013-0078133
Oct. 31, 2013 (KR) 10-2013-0131650

(51) Int. Cl. C23C 14/34; C23C 14/08; C23C 14/18; H05K 5/02; C23C 14/06

(52) U.S. Cl. CPC C23C 14/3485; H05K 5/0252; C23C 14/06; C23C 14/185; C23C 14/08
USPC 361/679.01; 204/192.12; 204/192.15; 428/457; 428/422; 428/450

(57) ABSTRACT

A method of manufacturing a multi-layer thin film is provided. The method includes modifying a surface of a plastic object by plasma treatment, depositing at least one hardness-enhancing layer on the plastic object, and depositing a color layer on the hardness-enhancing layer. The method may further include depositing a protective layer on the color layer.

### CROSS-REFERENCE TO RELATED APPLICATIONS

This application claims priority from Korean Patent Application Nos. 2013-0062485, 2013-0078133 and 2013-0131650, filed, respectively, on May 31, 2013, Jul. 4, 2013 and Oct. 31, 2013 in the Korean Intellectual Property Office, the disclosures of which are incorporated herein by reference.

### BACKGROUND

1. Field

Apparatuses and methods consistent with exemplary embodiments relate to a method of depositing target particles detached from a target by plasma discharge of inert gas on a plastic object.

2. Description of the Related Art

Plastic materials enable the manufacture of products with complicated shapes at a low cost due to the low weight and superior shaping freedom provided by plastic, as compared to metals, and a great deal of effort is being made to create a metallic appearance using plastic base materials.

Methods such as plating and sputtering are used to impart a metal-like texture to plastic injection-molding articles.

Plating is the most widely used method for this purpose. A plastic component is plated according to the following method. A molding powder, a release agent and the like are removed from the plastic by degreasing; palladium chloride, a catalyst to improve plating adhesion, is adsorbed on the plastic component, and nickel is precipitated on the catalyst layer to form a conductive thin film suitable for electroplating. Then, copper sulfate (CuSO4), nickel (Ni) and chromium (Cr) are sequentially electroplated onto the conductive thin film. Gold (Au), black pearl, rhodium (Rh) and the like may be used in place of chromium (Cr), according to desired color. After the final appearance of the coated film is obtained, the film is dehydrated and dried to complete the metal texture of the plastic component.

Sputtering is a physical vapor deposition (PVD) method of forming a coating layer before and after deposition so as to secure the hardness of the material and to protect the thin film. That is, coating layers used to increase hardness are sequentially formed on the bottom, a highly adhesive thin film is formed thereon and then a thin film layer having metal texture is deposited thereon. Finally, a coating layer is formed to protect the thin film.

### SUMMARY

One or more exemplary embodiments may provide a method of manufacturing a multi-layer thin film including depositing a hardness-enhancing layer and a color layer on a surface of a plastic material to enhance surface hardness of the plastic material and impart beautiful metal texture to the plastic material.

One or more exemplary embodiments may provide a plastic member having a multi-layer thin film having a hardness-enhancing layer, a color layer and a protective layer.

One or more exemplary embodiments may provide an electronic product having an outer appearance formed by a housing containing a plastic component and including a multi-layer thin film having a hardness-enhancing layer, a color layer and a protective layer formed on the entirety or part of a surface thereof.

Additional exemplary aspects will be set forth in part in the description which follows and, in part, will be obvious from the description, or may be learned by practice of the described exemplary embodiments.

According to an aspect of an exemplary embodiment, a method of manufacturing a multi-layer thin film includes modifying a surface of a plastic object by plasma treatment, depositing at least one hardness-enhancing layer on the plastic object and depositing a color layer on the hardness-enhancing layer.

The deposition of the hardness-enhancing layer on the plastic object may include depositing a first hardness-enhancing layer including chromium (Cr) on the plastic object and depositing a second hardness-enhancing layer including at least one material selected from a group consisting of titanium nitride (TiN), chromium nitride (CrN) and aluminum nitride (AlN) on the first hardness-enhancing layer.

In the deposition of the color layer on the hardness-enhancing layer, the color layer may include at least one material selected from a group consisting of chromium (Cr), titanium (Ti), copper (Cu), gold (Au) and titanium nitride (TiN).

The method may further include forming a protective layer including at least one material selected from a group consisting of polythtrafluoroethylene (PTFE) and silicon dioxide (SiO₂) on the color layer, after the deposition of the color layer on the hardness-enhancing layer.

According to an aspect of another exemplary embodiment, a plastic member includes a plastic object, at least one hardness-enhancing layer deposited on the plastic object to reinforce hardness of the plastic object and a color layer deposited on the hardness-enhancing layer to impart metallic appearance to the plastic object.

The hardness-enhancing layer may include a first hardness-enhancing layer including chromium (Cr) deposited on the plastic object and a second hardness-enhancing layer including at least one material selected from a group consisting of titanium nitride (TiN), chromium nitride (CrN) and aluminum nitride (AlN).

The color layer may include at least one of chromium (Cr), titanium (Ti), copper (Cu), gold (Au) and titanium nitride (TiN).

The plastic member may further include a protective layer including at least one material selected from a group consisting of polythtrafluoroethylene (PTFE) and silicon dioxide (SiO₂) deposited on the color layer.

According to an aspect of another exemplary embodiment, an electronic product includes a housing including a plastic component and a multi-layer thin film bonded to an entirety or a part of a surface of the housing, wherein the multi-layer thin film includes a coating layer bonded to the entirety or part of the surface of the housing, at least one hardness-enhancing layer bonded to the coating layer, and a color layer bonded to the hardness-enhancing layer.

The housing may include an accessory of the housing.

The plastic component may include one or more of polycarbonate (PC), acrylonitrile butadiene styrene (ABS) copolymers, polymethyl methacrylate (PMMA), methylmathacrylate/acrylonitrile/butadiene/styrene (MABS) and polycarbonate/acrylonitrile butadiene styrene (PC/ABS) copolymers.

The hardness-enhancing layer may include a first hardness-enhancing layer including chromium (Cr) deposited on the plastic object and a second hardness-enhancing layer including at least one material selected from a group consisting of titanium nitride (TiN), chromium nitride (CrN) and aluminum nitride (AlN).

The color layer may include at least one of chromium (Cr), titanium (Ti), copper (Cu), gold (Au) and titanium nitride (TiN).

The multi-layer thin film may further include a protective layer including at least one of polytetrafluoroethylene (PTFE) and silicon dioxide (SiO₂) deposited on the color layer.

### BRIEF DESCRIPTION OF THE DRAWINGS

These and/or other exemplary aspects and advantages will become apparent and more readily appreciated from the following description of exemplary embodiments, taken in conjunction with the accompanying drawings in which:

FIG. 1 is a view illustrating a configuration of a sputtering deposition apparatus used to manufacture a multi-layer thin film according to an exemplary embodiment;

FIGS. 2A, 2B and 2C illustrate a method of manufacturing a multi-layer thin film using the sputtering deposition apparatus having the configuration shown in FIG. 1;

FIG. 3 illustrates a sputtering deposition apparatus used to form a protective layer in addition to the configuration shown in FIG. 1;

FIG. 4 is a view illustrating a plastic member having a multi-layer thin film including a hardness-enhancing layer and a color layer deposited on a plastic object according to an exemplary embodiment;

FIG. 5 is a view illustrating a plastic member having a multi-layer thin film further including a protective layer deposited on the configuration shown in FIG. 4;

FIG. 6 illustrates a TV including a housing including the multi-layer thin film shown in FIG. 5 bonded to a surface thereof, as an example of an electronic product according to an exemplary embodiment;

FIG. 7A is a perspective view illustrating a communication equipment including a housing including the multi-layer thin film shown in FIG. 5 bonded to a surface thereof, as an example of an electronic product according to another exemplary embodiment;

FIG. 7B is a rear surface of the communication equipment shown in FIG. 7A;

FIG. 8 is a perspective view illustrating a washing machine having an outer appearance formed by a housing including the multi-layer thin film shown in FIG. 5 bonded to a surface thereof, as an example of an electronic product according to another exemplary embodiment; and

FIG. 9 is a perspective view illustrating a refrigerator having an outer appearance formed by a housing including the multi-layer thin film shown in FIG. 5 bonded to a surface thereof, as an example of an electronic product according to another exemplary embodiment.

### DETAILED DESCRIPTION

Reference will now be made in detail to the exemplary embodiments which are illustrated in the accompanying drawings, wherein like reference numerals refer to like elements throughout.

Hereinafter, a method of manufacturing a multi-layer thin film on a plastic object using a multi-layer thin film deposition device will be described with reference to the drawings.

A method of manufacturing a multi-layer thin film according to an exemplary embodiment includes modifying the surface of a plastic object by plasma treatment, depositing at least one hardness-enhancing layer on the plastic object, and depositing a color layer on the hardness-enhancing layer by a sputtering method. Hereinafter, the plastic object may be a plastic substrate or a processed product.

The deposition of at least one hardness-enhancing layer on the plastic object may include depositing a first hardness-enhancing layer containing chromium (Cr) on a coating layer and depositing, on the first hardness-enhancing layer, a second hardness-enhancing layer containing at least one component selected from the group consisting of titanium nitride (TiN), chromium nitride (CrN) and aluminum nitride (AlN).

The color layer deposited on the hardness-enhancing layer may contain at least one component selected from the group consisting of chromium (Cr), titanium (Ti), copper (Cu), gold (Au) and titanium nitride (TiN).

The method may further include depositing a protective layer containing at least one of PTFE and silicon dioxide (SiO₂) on the color layer.

In the method of manufacturing the multi-layer thin film according to this exemplary embodiment, the plasma treatment and the formation of the multi-layer thin film may be carried out using a sputtering method.

Sputtering is a representative physical vapor deposition method wherein atoms are ejected from a solid sample via energy generated during the collision of ionization-accelerated inert gas with the solid sample in a vacuum chamber. Sputtering is used to form or deposit thin film metal layers and metal oxide layers required to manufacture semiconductors, display devices, and the like.

The inert gas ionized in the vacuum chamber according to this exemplary embodiment may be argon (Ar) gas and may be used in combination with one or more other inert gases.

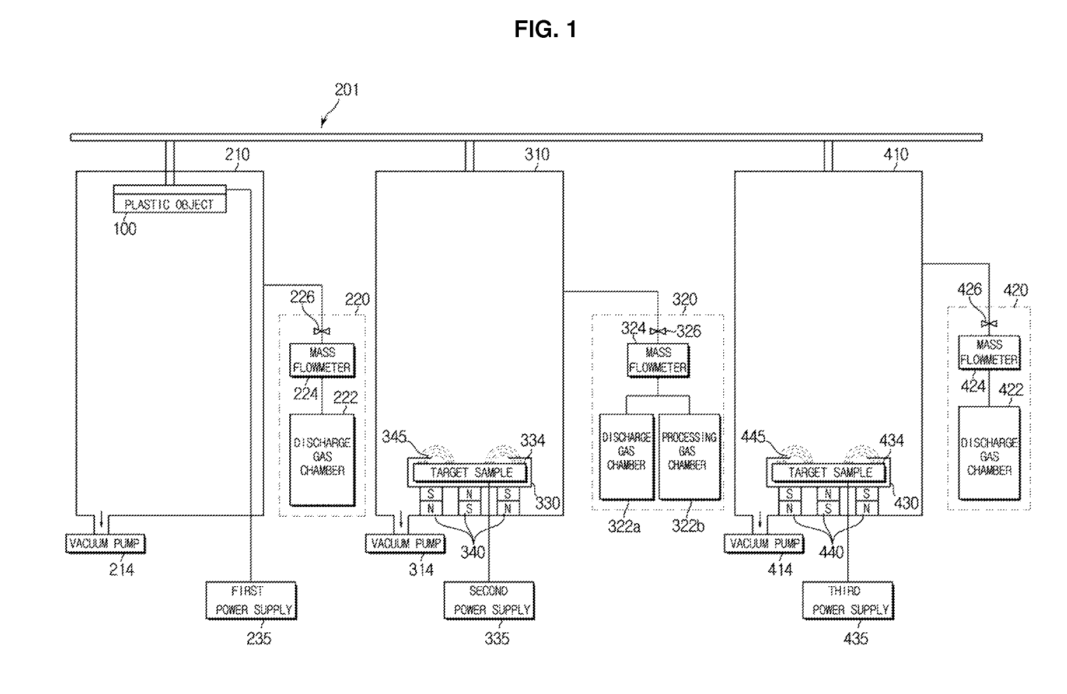

FIG. 1 is a view illustrating an example of a sputtering deposition apparatus 200 used to manufacture a multi-layer thin film according to an exemplary embodiment.

Referring to FIG. 1, the sputtering deposition apparatus 200, used to implement the manufacturing method according to an exemplary embodiment, includes a plurality of vacuum chambers 210, 310 and 410, a plurality of vacuum pumps 214, 314 and 414, a plurality of gas supply systems 220, 320 and 420, a rail 201, a plurality of guns 330 and 430, and a plurality of target samples 334 and 434. The sputtering deposition apparatus 200 may further include a plurality of magnetrons 340 and 440.

The vacuum pumps 214, 314 and 414 may be provided respectively at sides of the vacuum chambers 210, 310 and 410, or at the lower portion of the vacuum chambers 210, 310, and 410, as shown, and may maintain the vacuum states of the vacuum chambers 210, 310 and 410.

The gas supply systems 220, 320 and 420 may be provided respectively at sidewalls of the vacuum chambers 210, 310 and 410, and may supply gas to the vacuum chambers 210, 310 and 410.

Each of the gas supply systems 220, 320 and 420 may include a plurality of discharge gas chambers 222, 322a and 422 to store argon (Ar) gas to be ionized. The gas supply system 320 may include a processing gas chamber 322b to store nitrogen (N₂) gas which is a processing gas for plasma chemical deposition. The gas discharge chambers may also include, respectively, mass flowmeters 224, 324 and 424 to connect the vacuum chambers 210, 310 and 410 to the gas chambers 222, 322a, 322b and 422, and control valves 226, 326 and 426 to control flow of gas from the gas chambers 222, 322a, 322b and 422 to the vacuum chambers 210, 310 and 410.

The rail 201 is provided at an upper end of the vacuum chambers 210, 310 and 410 and an object, on which the materials are to be deposited, is mounted on the rail 201. The object may be a planar plastic object 100 or may be a component including a plastic material having a curved surface or a protrusion on a part of a surface thereof.

Target samples 334 and 434 are provided, respectively, within the vacuum chambers 310 and 410 and are disposed opposite to the object. The object may have a planar or curved shape. The target samples 334 and 434 may be selected according to the shape of the object.

The guns 330 and 430 are provided, respectively, within the vacuum chambers 310 and 410 and are connected to a cathode through the second and third power supplies 335 and 435. When the second and third power supplies 335 and 435 supply power to the guns 330 and 430, a negative electric field is generated and argon (Ar) gas begins discharging and collides with electrons supplied from the second and third power supplies 335 and 435, to produce argon ions (Ar⁺) and generate plasma.

The magnetrons 340 and 440 are provided, respectively, within the vacuum chambers 310 and 410 and a plurality of the magnetrons 340 and a plurality of the magnetrons 440 are mounted, respectively, under the target samples 334 and 434.

Magnetic fields 345 and 445 are generated by the magnetrons 340 and 440. Electrons isolated from argon (Ar) move along helical paths when they ate acted upon by the force of the generated magnetic fields as well as the force of the magnetic fields formed by the magnetrons 340 and 440.

The electrons moving along helical paths are captured by the magnetic fields and do not readily escape therefrom, and thus, the density of the electrons in plasma increases.

For this reason, the level of argon (Ar) atoms ionized in the vacuum chambers 310 and 410 increases, the number of argon (Ar) atoms which collide with the target samples 334 and 434 also increases, and the efficiency of the thin film deposition thus improves.

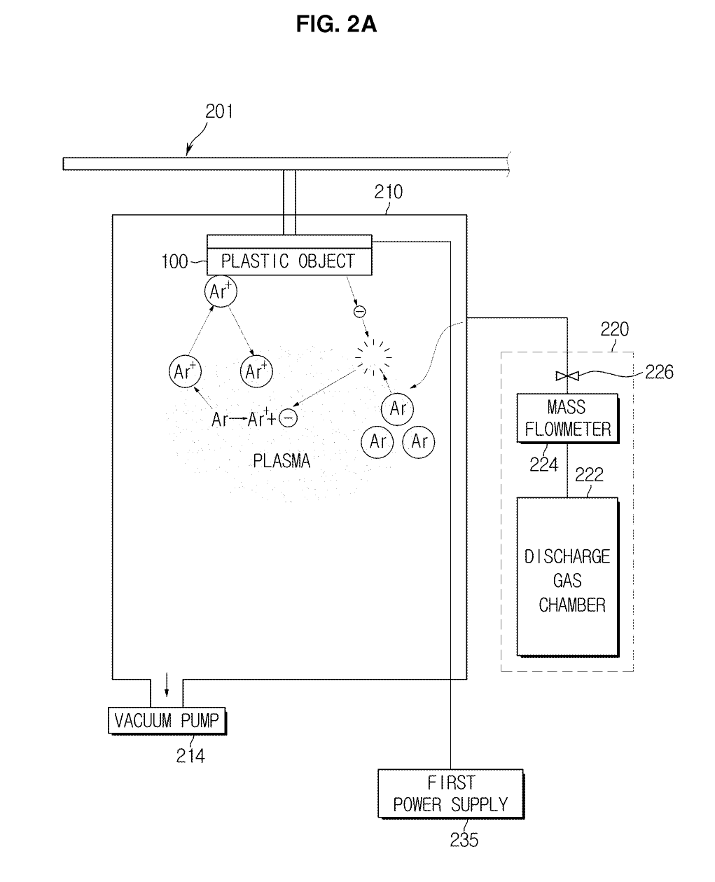

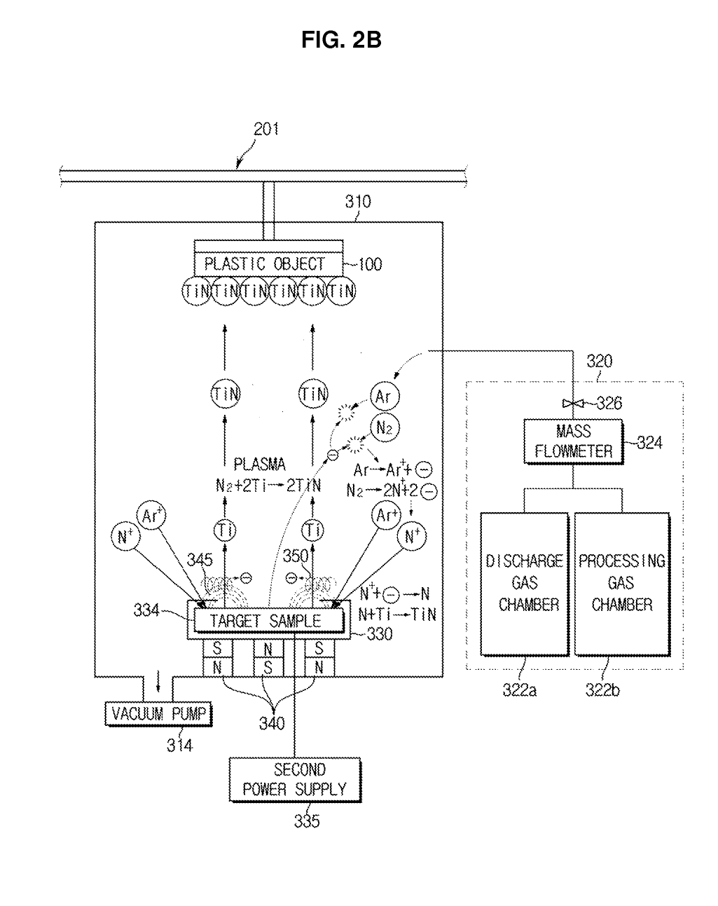

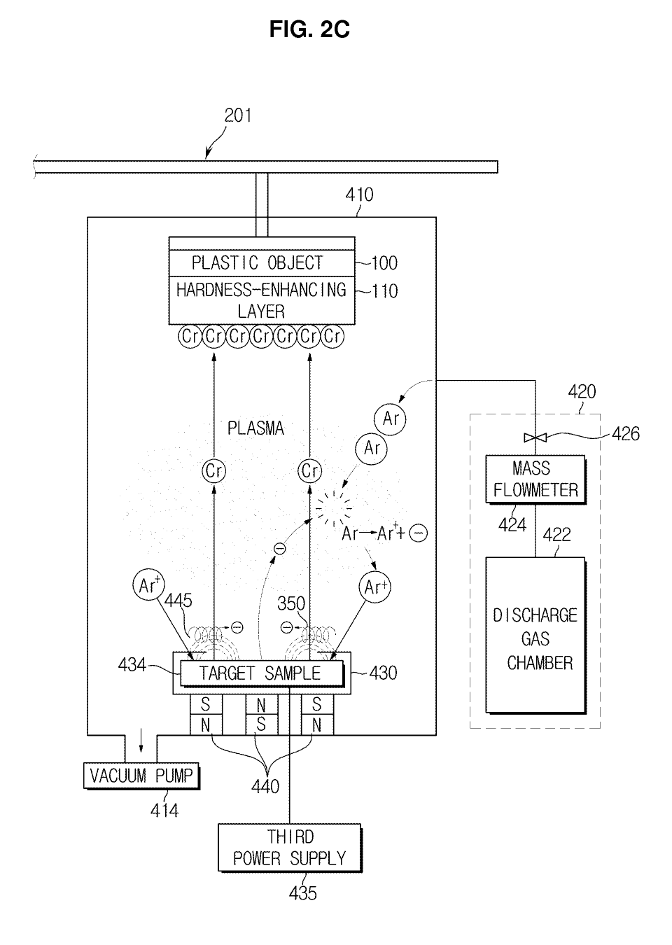

FIGS. 2A, 2B and 2C illustrate a method of manufacturing a multi-layer thin film according to an exemplary embodiment using the sputtering deposition apparatus 200 having a configuration as shown in FIG. 1.

The method of manufacturing a multi-layer thin film according to this exemplary embodiment includes modifying a surface of a plastic object 100 by plasma treatment, depositing a hardness-enhancing layer 110 on the plastic object 100, and depositing a color layer 120 on the hardness-enhancing layer 110.

The hardness-enhancing layer 110 may include a first hardness-enhancing layer containing chromium (Cr) and a second hardness-enhancing layer containing at least one material selected from a group consisting of chromium nitride (CrN), titanium nitride (TiN) and aluminum nitride (AlN). The color layer 120 may contain at least one material selected from a group consisting of chromium (Cr), titanium (Ti), copper (Cu), gold (Au) and titanium nitride (TiN), as described above.

Hereinafter, an exemplary method of manufacturing a multi-layer thin film including depositing a hardness-enhancing layer 110 containing titanium nitride (TiN) and depositing a color layer 120 containing chromium (Cr) will be described.

During deposition, temperatures of the target samples 334 and 434 are maintained within a range from room temperature to about 200° C. or less and a temperature of the object moving along the rail 201 is maintained at about 60° C. to 70° C.

The method of manufacturing the multi-layer thin film will be described below with reference to FIGS. 2A, 2B and 2C.

Referring to FIG. 2A, a processed plastic object 100 is loaded into a first vacuum chamber 210 of the sputtering deposition apparatus 200 and is surface-modified by plasma irradiation under predetermined conditions.

When a first power supply 235 supplies power to generate a negative magnetic field, discharge begins in the first vacuum chamber 210 to produce plasma.

More specifically, the argon (Ar) gas supplied to the first vacuum chamber 210 collides with primary and tertiary electrons and is then ionized and cleaved into a cation and an electron, as depicted by the following Reaction Scheme 1, to produce plasma.

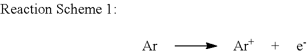

As the discharge gas for modification, argon (Ar) gas may be used alone or in combination with another inert gas. The following description is given on the assumption that argon (Ar) gas is used as the discharge gas.

A DC power source, a pulsed DC power source, or a radio frequency (RF) power source may be used as the power supply. Of these, the RF power source, which prevents damage of the plastic object 100 during plasma treatment and maximizes modification by plasma heating may be used as the first power supply 235.

More specifically, the RF power source repeatedly changes power applied to a target at a frequency of 13.56 MHz from a negative value to a positive value or from a positive value to a negative value. In this case, when the target to which power is applied is a cathode, a plasma-state argon ion (Ar⁺) is accelerated toward the plastic object 100, but the target to which power is supplied is changed to an anode when the argon ion is attached on the surface of plastic object 100 after sputtering and the argon ion is separated from the surface thereof. The RF power source is preferably used for modification of the plastic object 100 which is a non-conductor because the plasma state is maintained based on such a principle.

After completion of modification of the plastic object 100, a multi-layer thin film is deposited on the surface of the plastic object 100 by a sputtering method.

More specifically, in order to deposit the hardness-enhancing layer 110 on the surface-modified plastic object 100, as shown in FIG. 2B, the plasma-treated plastic object 100 is mounted in the second vacuum chamber 310, titanium (Ti) is placed on the target sample 334 disposed thereunder, and argon (Ar) gas and nitrogen (N₂) gas are supplied to the second vacuum chamber 310 while maintaining an inner atmosphere of the second vacuum chamber 310 under vacuum by a vacuum pump 314 and controlling a mass flowmeter 326.

Then, discharge begins when the second power supply 335 supplies power to the gun 330 and reactions occur to produce plasma ionized from argon (Ar) gas and nitrogen (N₂) gas, as depicted by Reaction Scheme 1 above and Reaction Scheme 2 described below.

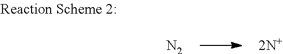

All nitrogen (N₂) molecules are not ionized. That is, some nitrogen molecules are present in a molecular state and others are present in an ionized state.

The argon ions (Ar⁺) and nitrogen ions (N⁺) are accelerated and drawn toward the titanium (Ti) target sample 334 serving as a cathode upon application of a magnetic field thereto, the accelerated argon ions (Ar⁺) collide with the titanium (Ti) target sample 334 to transfer energy to the surface of the target sample 334 and titanium atoms (Ti) are ejected from the target sample 334.

The titanium (Ti) atoms having high energy react with nitrogen gas injected into the second vacuum chamber 310 to produce the hardness-enhancing layer 110 containing titanium nitride (TiN), as depicted by the following Reaction Scheme 3.

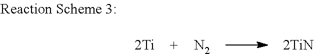

As depicted by the following Reaction Scheme 4, the nitrogen iona (N⁺), which are accelerated and drawn toward the titanium (Ti) target sample 334 and are then partially ionized, each receive an electron while colliding with the target sample 334 and are then neutralized (as shown in Reaction Scheme 4(1)), and some of them react with titanium (Ti) to produce titanium nitride (TiN) (as shown in Reaction Scheme 4 (2)).

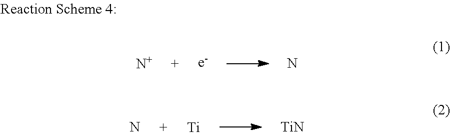

In this reaction scheme, some of titanium nitride (TiN) produced by the reaction remains on the surface of the target sample 334, thus causing color change of the target.

A DC power source, a pulsed DC power source or a radio frequency power source (RF power source) may be used as the second power supply 335. Of these, the DC power source produces a low density of deposited layers, and the RF power source produces a low deposition efficiency due to the low deposition rate of titanium nitride (TiN). Thus, a pulsed DC power source may be preferably used.

A voltage of the pulsed DC power source may be greater than about 0V and not greater than about 600V. the power and deposition time may be controlled so that the hardness-enhancing layer 110 is formed to a thickness of about 1 to 500 nanometers.

A pulsed DC power source has deposition efficiency higher than an RF power source but lower than a DC power source. Accordingly, deposition of titanium nitride (TiN) may be performed in another chamber that is the same as the second vacuum chamber 310.

After formation of the hardness-enhancing layer 110, the plastic object 100 is moved along the rail 201 and is mounted in the third vacuum chamber 410, as shown in FIG. 2C so as to deposit the color layer 120 on the hardness-enhancing layer 110. After the mounting of the hardness-enhancing layer 110-deposited plastic object 100 in the third vacuum chamber 410, argon (Ar) gas is supplied to the third vacuum chamber 410 while maintaining an atmosphere of the third vacuum chamber 410 under vacuum by the vacuum pump 414 and controlling a mass flowmeter 426.

Then, plasma is produced in the same manner as in the first vacuum chamber 210, positively-charged argon ions (Ar⁺) collide with the chromium (Cr) target sample 434, and chromium (Cr) atoms are ejected from the target sample 434 and are deposited on the hardness-enhancing layer 110 containing titanium nitride (TiN) to form a color layer 120 containing chromium (Cr).

A DC power source, a pulsed DC power source or a radio frequency power source (RF power source) may be used as the third power supply 435. Of these, the DC power source produces a low density of deposited layers, and the RF power source produces a low deposition efficiency due to low deposition rate of titanium nitride (TiN). Thus, the pulsed DC power source may be preferably used.

A voltage of the pulsed DC power source may be greater than about 0V and not greater than about 600V. Power and deposition time may be controlled so that the color layer 120 is formed to a thickness of about 1 to 500 nanometers.

The method may further include depositing a protective layer 130 containing PTFE or silicon dioxide on the color layer 120 after formation of the color layer 120 containing chromium (Cr) on the hardness-enhancing layer 110 containing titanium nitride (TiN). Hereinafter, a process of depositing the protective layer 130 containing PTFE will be described by way of example.

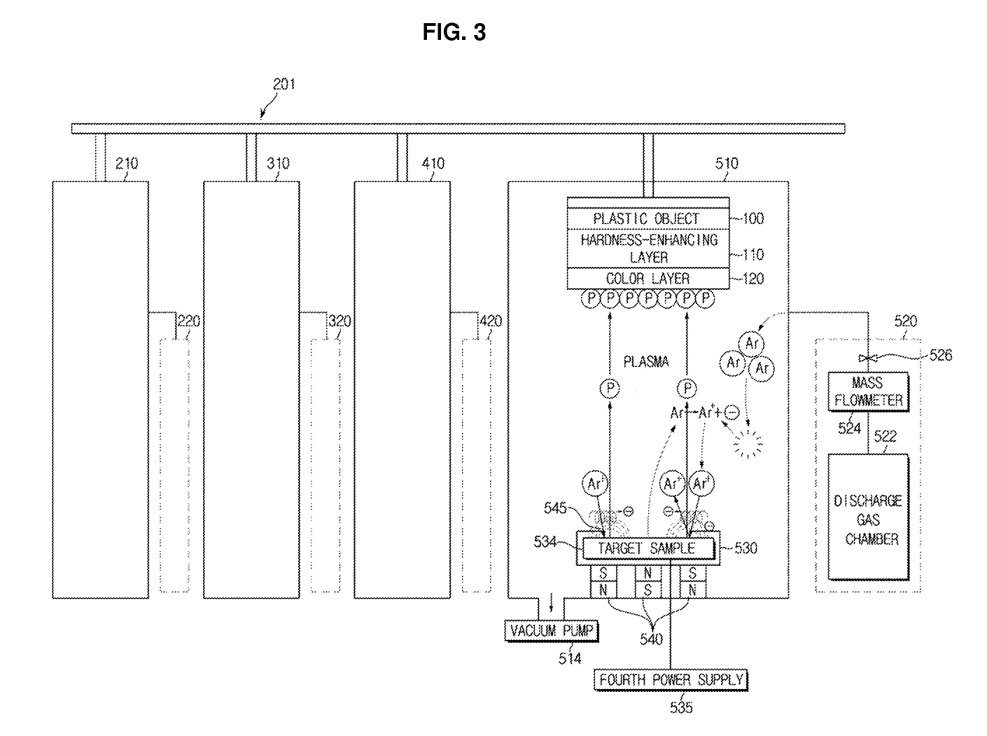

FIG. 3 illustrates a sputtering deposition apparatus 500 for forming the protective layer 130. As shown in FIG. 3, a fourth vacuum chamber 510 may be further provided in the sputtering deposition apparatus 200 shown in FIG. 2 so as to further perform the process of forming the protective layer 130.

For formation of the protective layer 130, the plastic object 100 is moved to and mounted in the fourth vacuum chamber 510. When the plastic object 100, on which the hardness-enhancing layer 110 and the color layer 120 are deposited, is mounted in the fourth vacuum chamber 510, argon (Ar) gas is supplied to the fourth vacuum chamber 510 while maintaining an atmosphere of the fourth vacuum chamber 510 under vacuum by the vacuum pump 514 and controlling a mass flowmeter 524.

Then, plasma is produced in the same manner as in the first vacuum chamber 210, positively-charged argon ions (Ar⁺) collide with a PTFE (P) target sample and PTFE is ejected and is deposited on the color layer 120 to form the protective layer 130.

The RF power source may be used as the fourth power supply 535 according to the same principle as plasma treatment, because PTFE is a non-conductor. The RF power source may be used for deposition of silicon dioxide as well because silicon dioxide is a non-conductor.

In addition, the power and the deposition time are controlled so that the protective layer 130 is formed to a thickness of about 1 to 500 nanometers, or to a thickness of about 30 to 300 nanometers.

The protective layer 130 containing PTFE or silicon dioxide prevents fingerprints from being left on the multi-layer thin film due to anti-fingerprinting function and protects the multi-layer thin film from being physically scratched. For these reasons, the protective layer 130 may be formed on the color layer 120.

Hereinafter, a plastic member according to an exemplary embodiment will be described in detail with reference to the annexed drawings.

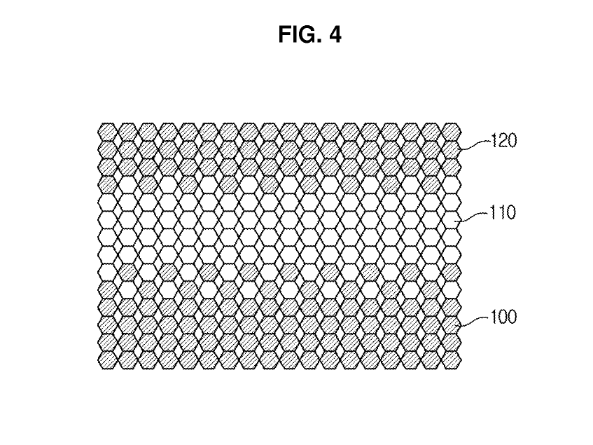

FIG. 4 is a view illustrating a structure of an exemplary plastic member. As shown in FIG. 4, the plastic member includes a plastic object 100, a hardness-enhancing layer 110 deposited on the plastic object 100, and a color layer 120 deposited on the hardness-enhancing layer 110.

The plastic object 100 is free from foreign matter and is made flat through plasma treatment.

The hardness-enhancing layer 110 may include a first hardness-enhancing layer containing chromium (Cr) deposited on the plastic object 100 and a second hardness-enhancing layer containing at least one material selected from a group consisting of titanium nitride (TiN), chromium nitride (CrN) and aluminum nitride (AlN).

The color layer 120 may contain at least one material selected from the group consisting of chromium (Cr), titanium (Ti), copper (Cu), gold (Au) and titanium nitride (TiN).

Regarding a combination of the first hardness-enhancing layer, the second hardness-enhancing layer and the color layer 130 containing these substances, the first hardness-enhancing layer may contain at least one type of component, the second hardness-enhancing layer may contain at least three types of components, and the color layer 120 may contain at least five types of components, thus providing possible combinations of at least fifteen types of components.

Meanwhile, the fifteen combinations may include combinations in which identical components are continuously deposited, as in a case in which the second hardness-enhancing layer contains titanium nitride (TiN) and the color layer 130 also contains titanium nitride (TiN). However, it may be difficult to accomplish desired effects such as hardness enhancement with combinations in which identical components are continuously deposited. Accordingly, continuous layers may include different components.

Hereinafter, a structure in which a hardness-enhancing layer 110 containing titanium nitride (TiN) is deposited on the plastic object 100 and a color layer 120 containing chromium (Cr) is deposited thereon will be described in detail.

Titanium nitride (TiN) and chromium (Cr) are deposited by a sputtering method. In accordance with the sputtering method, the atoms collide with a substrate at a relatively high momentum as compared to other PVD methods, thus providing a strong bonding force between the atoms and the substrate. Referring to FIG. 4, titanium nitride (TiN) molecules constituting the hardness-enhancing layer 110 are deeply embedded in the plastic object 100 and chromium (Cr) atoms are deeply embedded in the hardness-enhancing layer 110 containing titanium nitride (TiN). The embodiment is formed when titanium nitride (TiN) molecules and chromium (Cr) atoms collide with the plastic object 100 and are deeply embedded therein during the sputtering deposition.

For this reason, the hardness-enhancing layer 110 is bonded to the plastic object 100 at a strong bonding energy and the strong bond energy improves the hardness of the plastic object 100 and thus enhances the anti-scratch properties of the plastic. Current density in plasma and temperature may be controlled so that titanium nitride (TiN) molecules or chromium (Cr) atoms are effectively embedded in the plastic substrate.

The hardness-enhancing layer 110 may be formed to a thickness of about 1 to 500 nanometers. When a plurality of hardness-enhancing layers including the hardness-enhancing layer 110 are present, the respective hardness-enhancing layers 110 may be formed to the thickness of about 1 to 500 nanometers. In addition, the color layer 120 may be formed to a thickness of about 1 to 500 nanometers.

Hereinafter, a structure of another exemplary plastic member will be described in detail.

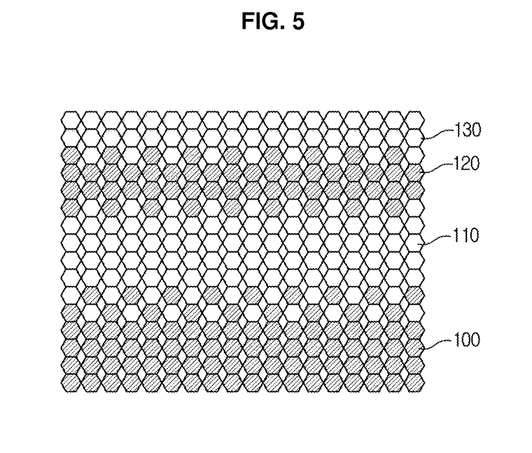

FIG. 5 illustrates a structure of a plastic member having a multi-layer thin film according to an exemplary embodiment. Referring to FIG. 5, the multi-layer thin film may include a protective layer 130 further containing PTFE or silicon dioxide while having the structure shown in FIG. 4.

The protective layer 130 containing at least one of PTFE and silicon dioxide has N anti-fingerprinting property due to a contact angle to water, thus preventing fingerprints from being left on the metal thin film layer. In addition, the protective layer 130 protects the metal thin film and the plastic object 100 from scratches due to the high hardness thereof.

The protective layer 130 to protect the metal thin film and the plastic object 100 may be formed to a thickness of about 1 to 500 nanometers, or to a thickness of about 30 to 300 nanometers.

Hereinafter, an electronic product according to an exemplary embodiment will be described in detail.

An electronic product includes a housing containing a plastic component and a multi-layer thin film bonded to an entirety of or a part of the surface of the housing, wherein the multi-layer thin film includes a coating layer bonded to an entirety of or a part of the surface of the housing, at least one hardness-enhancing layer bonded to the coating layer and a color layer bonded to the hardness-enhancing layer.

The housing may be a substantially box-shaped part surrounding a mechanical apparatus, such as a box-type housing accommodating components therein or a frame containing instruments therein and may include one or more housing accessories. Housing accessories portions of the housing used to constitute the outer appearance of the housing, such as bezel portions of televisions (TVs), stands of TVs, and bezel portions of telecommunication equipment, or components of an electronic product.

In addition, the expression “housing contains a plastic component” means that the housing contains a homopolymer or a heteropolymer obtained by polymerizing two or more homopolymers. More specifically, the housing may contain at least one of polycarbonate (PC), acrylonitrile butadiene styrene (ABS) copolymers, polymethyl methacrylate (PMMA), and methylmathacrylate/acrylonitrile/butadiene/styrene (MABS).

A surface of the plastic object 100 on which the multi-layer thin film is formed is a surface of the plastic object 100 from which foreign matter is removed by plasma treatment.

The hardness-enhancing layer 110 may include a first hardness-enhancing layer containing chromium (Cr) deposited on the plastic object 100 and a second hardness-enhancing layer containing at least one selected from the consisting of titanium nitride (TiN), chromium nitride (CrN) and aluminum nitride (AlN).

The color layer 120 may contain at least one selected from the group consisting of chromium (Cr), titanium (Ti), copper (Cu), gold (Au) and titanium nitride (TiN).

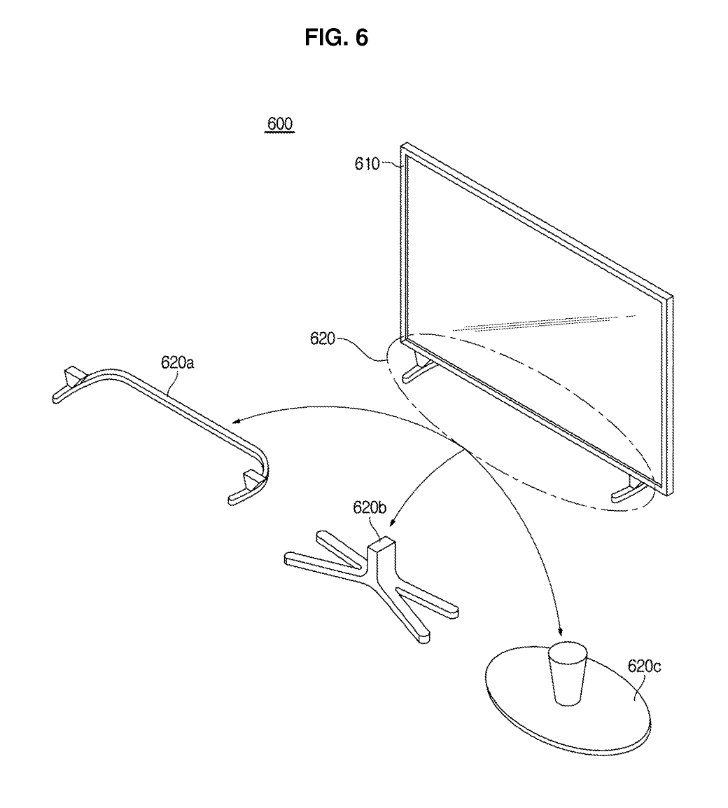

FIG. 6 illustrates a TV 600 including a housing including the multi-layer thin film shown in FIG. 5 bonded to a surface thereof, as an example of an electronic product according to an exemplary embodiment.

As shown in FIG. 6, the TV 600 may include a bezel portion 610 having the multi-layer thin film formed thereon and stand portions 620a, 620b and 620c also having the multi-layer thin film formed thereon. Such a housing having the multi-layer thin film formed thereon provides improved hardness and a beautiful metal texture.

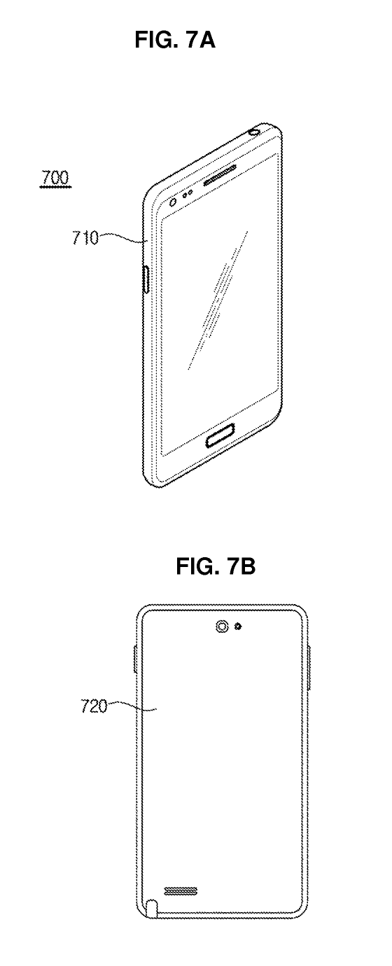

FIG. 7A is a perspective view illustrating communication equipment 700 including a housing including the multi-layer thin film shown in FIG. 5 bonded to a surface thereof, as an example of an electronic product according to another exemplary embodiment, and FIG. 7B is a rear surface of the communication equipment 700.

As shown in FIGS. 7A and 7B, the housing used to form an outer appearance of the communication equipment 700 may have the multi-layer thin film, shown in FIG. 5, formed thereon, thus reinforcing the hardness of the communication equipment 700 and imparting an outer appearance with a beautiful metal texture thereto.

As described above, the housing may include a bezel portion 710 of the communication equipment 700 and a case portion 720 of the communication equipment 700.

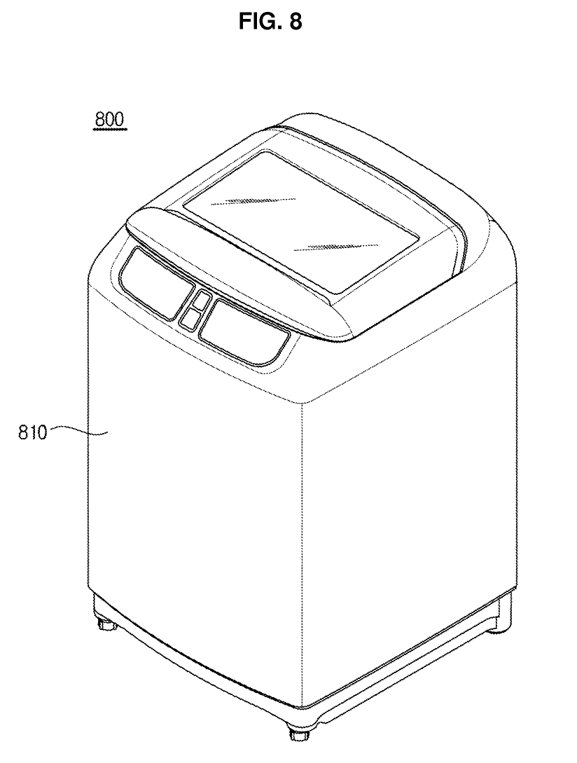

FIG. 8 is a perspective view illustrating a washing machine 800 having an outer appearance formed by a housing 810 having the multi-layer thin film shown in FIG. 5 bonded to a surface thereof, as an example of an electronic product according to another exemplary embodiment.

As shown in FIG. 8, the housing 810 used to form an outer appearance of the washing machine 800 may include the multi-layer thin film shown in FIG. 5, thus reinforcing the hardness of the washing machine 800 and imparting an outer appearance with a beautiful metal texture thereto.

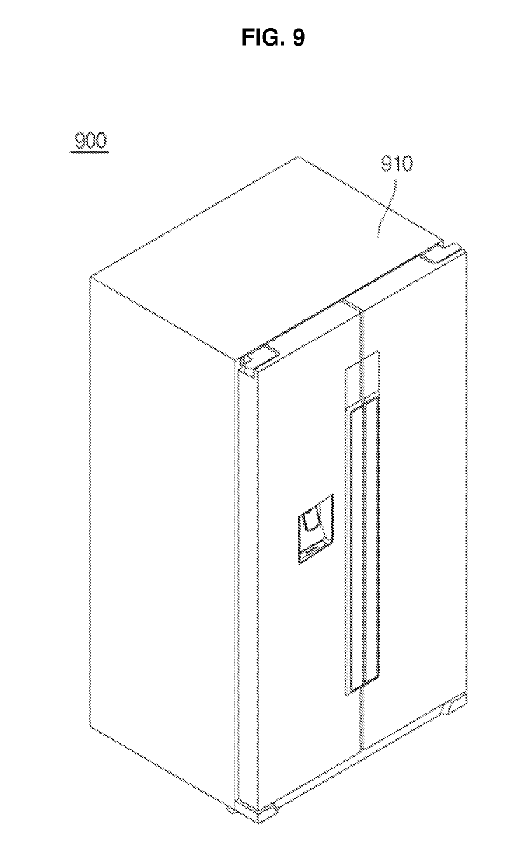

FIG. 9 is a perspective view illustrating a refrigerator 900 having an outer appearance formed by a housing 910 having the multi-layer thin film shown in FIG. 5 bonded to a surface thereof, as an example of an electronic product according to another exemplary embodiment.

The housing 910 used to form an outer appearance of the refrigerator 900 shown in FIG. 9 may include the multi-layer thin film shown in FIG. 5 and consequently may reinforce the hardness of the refrigerator 900 and impart an outer appearance with a beautiful metal texture thereto.

As apparent from the forgoing descriptions, the hardness of a plasma-treated plastic object may be reinforced by depositing a hardness-enhancing layer containing at least one component of chromium nitride (CrN), titanium nitride (TiN), aluminum nitride (AlN) and chromium (Cr) on the plastic object.

In addition, a beautiful metal texture may be imparted to the plastic material by depositing a color layer containing at least one component of chromium (Cr), titanium (Ti), copper (Cu), gold (Au) and titanium nitride (TiN) on the plastic material.

The multi-layer thin film may be formed by a sputtering deposition method which is a dry deposition method and is thus eco-friendly.

Although a few exemplary embodiments have been shown and described, it would be appreciated by those skilled in the art that changes may be made in these embodiments without departing from the principles and spirit of the inventive concept, the scope of which is defined in the following claims and their equivalents.

What is claimed is:

1. A method of manufacturing a multi-layer thin film, the method comprising:
modifying a surface of a plastic object by plasma treatment;
depositing at least one hardness-enhancing layer on the plastic object; and
depositing a color layer on the at least one hardness-enhancing layer.

2. The method according to claim 1, wherein the depositing the at least one hardness-enhancing layer on the plastic object comprises:
depositing a first hardness-enhancing layer comprising chromium (Cr) on the plastic object; and
depositing a second hardness-enhancing layer, comprising at least one material selected from a group consisting of titanium nitride (TiN), chromium nitride (CrN) and aluminum nitride (AlN), on the first hardness-enhancing layer.

3. The method according to claim 1, wherein the color layer comprises at least one material selected from a group consisting of chromium (Cr), titanium (Ti), copper (Cu), gold (Au) and titanium nitride (TiN).

4. The method according to claim 1, further comprising:
forming a protective layer on the color layer, the protective layer comprising at least one material selected from a group consisting of polythtrafluoroethylene (PTFE) and silicon dioxide (SiO₂).

5. A plastic member comprising:
a plastic object;
at least one hardness-enhancing layer deposited on the plastic object; and
a color layer deposited on the at least one hardness-enhancing layer.

6. The plastic member according to claim 5, wherein the at least one hardness-enhancing layer comprises:
a first hardness-enhancing layer comprising chromium (Cr) deposited on the plastic object; and
a second hardness-enhancing layer comprising at least one material selected from a consisting of titanium nitride (TiN), chromium nitride (CrN) and aluminum nitride (AlN).

7. The plastic member according to claim 5, wherein the color layer comprises at least one material selected from a group consisting of chromium (Cr), titanium (Ti), copper (Cu), gold (Au) and titanium nitride (TiN).

8. The plastic member according to claim 5, further comprising a protective layer deposited on the color layer, the protective layer comprising at least one material selected from a group consisting of polythtrafluoroethylene (PTFE) and silicon dioxide (SiO₂).

9. An electronic product comprising:
a housing comprising a plastic component; and
a multi-layer thin film bonded to a surface of the plastic component, wherein the multi-layer thin film comprises:
a coating layer bonded to the surface of the plastic component;
at least one hardness-enhancing layer bonded to the coating layer; and
a color layer bonded to the at least one hardness-enhancing layer.

10. The electronic product according to claim 9, wherein the housing further comprises at least one accessory.

11. The electronic product according to claim 9, wherein the plastic component comprises at least one material selected from a group consisting of polycarbonate (PC), acrylonitrile butadiene styrene (ABS) copolymers, polymethyl methacrylate (PMMA), methylmathacrylate/acrylonitrile/butadiene/styrene (MABS) and polycarbonate/acrylonitrile butadiene styrene (PC/ABS) copolymers.

12. The electronic product according to claim 9, wherein the at least one hardness-enhancing layer comprises:
a first hardness-enhancing layer comprising chromium (Cr) deposited on the plastic component; and
a second hardness-enhancing layer comprising at least one material selected from a consisting of titanium nitride (TiN), chromium nitride (CrN) and aluminum nitride (AlN).

13. The electronic product according to claim 9, wherein the color layer comprises at least one material selected from a group consisting of chromium (Cr), titanium (Ti), copper (Cu), gold (Au) and titanium nitride (TiN).

14. The electronic product according to claim 9, wherein the multi-layer thin film further comprises a protective layer deposited on the color layer, wherein the protective layer comprises at least one of polytetrafluoroethylene (PTFE) and silicon dioxide (SiO₂).

15. A method of coating a plastic object, the method comprising:
applying a plasma treatment to a surface of the plastic object;
applying a hardness-enhancing layer to a plasma-treated surface of the plastic object using a sputtering method;
applying a color layer on the hardness-enhancing layer using a sputtering method.

16. The method according to claim 15, wherein the applying the plasma treatment, the applying the hardness-enhancing layer, and the applying the color layer each comprise using a pulsed direct current power source.

17. The method according to claim 15, wherein the applying the hardness-enhancing layer comprises applying a first hardness-enhancing layer, and applying a second hardness-enhancing layer.

18. The method according to claim 15, further comprising applying a protective layer on the color layer using a sputtering method.
